(19) United States
(12) Patent Application Publication
(10) Pub. No.: US 2025/0260185 A1
(43) Pub. Date: Aug. 14, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/045,551

(22) Filed: Feb. 5, 2025

(30) Foreign Application Priority Data
Feb. 14, 2024 (JP) 2024-020365

(51) Int. Cl. H01R 12/55; H01L 23/538

(52) U.S. Cl. CPC H01R 12/55; H01L 23/5386

(57) ABSTRACT

An electronic module includes: a flat-shaped power terminal; and an internal connection frame supporting the power terminal and electrically connecting electronic elements to the power terminal. The power terminal includes: an insertion portion which extends in a direction toward a board from the internal connection frame; and a large width portion which extends in a direction opposite to the board from the internal connection frame. The insertion portion is press-fitted into an elongated hole formed in the internal connection frame and a distal end of the insertion portion is brought into contact with the board, and a portion which protrudes in a thickness direction of the power terminal from one side surface and a portion which protrudes in a thickness direction of the power terminal from the other side surface of the power terminal are formed on a boundary portion between the insertion portion and the large width portion.

### CROSS REFERENCE TO RELATED APPLICATIONS

This application claims priority to Japanese Patent Application No. 2024-20365, filed on Feb. 14, 2024, which is expressly incorporated herein by reference in its entirety.

### TECHNICAL FIELD

The present invention relates to an electronic module.

### BACKGROUND ART

Conventionally, there has been known an electronic module (semiconductor module) that includes: a board on which a semiconductor chip is mounted; a pin terminal which is connected to a wiring pattern disposed on the board; and a lead frame that supports a pin terminal and electrically connects an electrode of the semiconductor chip and the pin terminal to each other (see patent literature 1 described below). The pin terminal is press-fitted into a hole formed in the lead frame. The pin terminal can be made self-standing by supporting the pin terminal by a flange portion formed at an intermediate position, and the flange portion allows wetting and spreading of solder on the pin terminal.

In the conventional module, an electrode is taken out to the outside using a pin terminal. However, it is difficult to largely increase a cross-sectional area of a current path and hence, it is difficult to supply a large current to the electronic module. In view of the above-mentioned circumstance, the use of a plate-shaped power terminal is proposed for reducing inductance and a wiring resistance (see FIG. 4).

As illustrated in FIG. 4, an electronic module 300 includes two semiconductor elements 320A, 320B formed on one surface of an insulation board 312. A first terminal 330 is disposed in front of the electronic module 300 in the longitudinal direction. A first connection frame 332 is electrically connected to the first terminal 330, and is integrally formed with the first terminal 330. A second connection frame 342 is electrically connected to a second terminal 340. The electronic module 300 further includes a third terminal 360 having a plate shape as a power terminal. The third terminal 360 is formed in an elongated shape, and is disposed such that a front-and-back direction is taken in a plate thickness direction, and a vertical direction is set as a longitudinal direction.

### PRIOR ART LITERATURE

### Patent Literature

[Japanese Patent Literature 1] Japanese patent 6850938

### SUMMARY OF INVENTION

### Technical Problem

However, it is difficult to form a flange portion to a power terminal having a flat plate shape. Accordingly, unlike the pin terminal on which the flange portion is formed, problems still remain such that it is difficult to make the power terminal self-standing in a stable manner, and it is also difficult to enable stable wetting and spreading of solder (a conductive bonding material) between the power terminal and the lead frame.

The present invention has been made in view of the above-mentioned drawbacks, and it is an object of the present invention to provide an electronic module which enables the stable self-standing of a power terminal and enables the stable wetting and spreading of solder (a conductive bonding material) between the power terminal and a lead frame.

### Solution to Problem

An electronic module according to the present invention includes: a board on which an electronic element is mounted; a power terminal having a flat plate shape which is connected to a wiring pattern on the board; and an internal connection frame which supports the power terminal and electrically connects the electronic element and the power terminal to each other, wherein the internal connection frame is a member having a flat plate shape that has an elongated hole, the power terminal includes: an insertion portion which extends in a direction toward the board from the internal connection frame; and a large width portion which extends in a direction opposite to the board from the internal connection frame, the power terminal is electrically connected to the internal connection frame, the insertion portion is press-fitted into the elongated hole formed in the internal connection frame and a distal end portion of the insertion portion is brought into contact with the board, and a protruding portion which protrudes in a thickness direction of the power terminal from one side surface of the power terminal and a protruding portion which protrudes in a thickness direction of the power terminal from the other side surface of the power terminal are formed on a boundary portion between the insertion portion and the large width portion.

### Advantageous Effects of the Present Invention

According to the electronic module of the present invention, the protruding portion which protrudes in a thickness direction of the power terminal from one side surface and the protruding portion which protrudes in a thickness direction of the power terminal from the other side surface of the power terminal are formed on the boundary portion between the insertion portion and the large width portion and hence, it is possible to enable the stable self-standing of the power terminal and, at the same time, it is also possible to enable the stable wetting and spreading of solder (a conductive bonding material) between the power terminal and a lead frame.

### BRIEF DESCRIPTION OF DRAWINGS

FIG. 1 is a perspective view illustrating an external appearance of an electronic module 100 according to an embodiment 1.

FIG. 2 is a perspective view illustrating a structure of a power terminal.

FIG. 3A and FIG. 3B are views illustrating a protruding portion of the power terminal. FIG. 3A is a cross-sectional view taken along a line X-X in FIG. 2, and FIG. 3B is a view illustrating wetting and spreading of solder formed in the vicinity of the protruding portion of the power terminal.

FIG. 4 is a view illustrating an electronic module 300 according to a prior art.

### DESCRIPTION OF EMBODIMENTS

Hereinafter, the electronic module according to one embodiment of the present invention is described. The embodiment described hereinafter is not intended to limit the present invention called for in claims. Further, it is not always the case that all of various elements described in the embodiment and combinations of these elements are indispensable in the present invention.

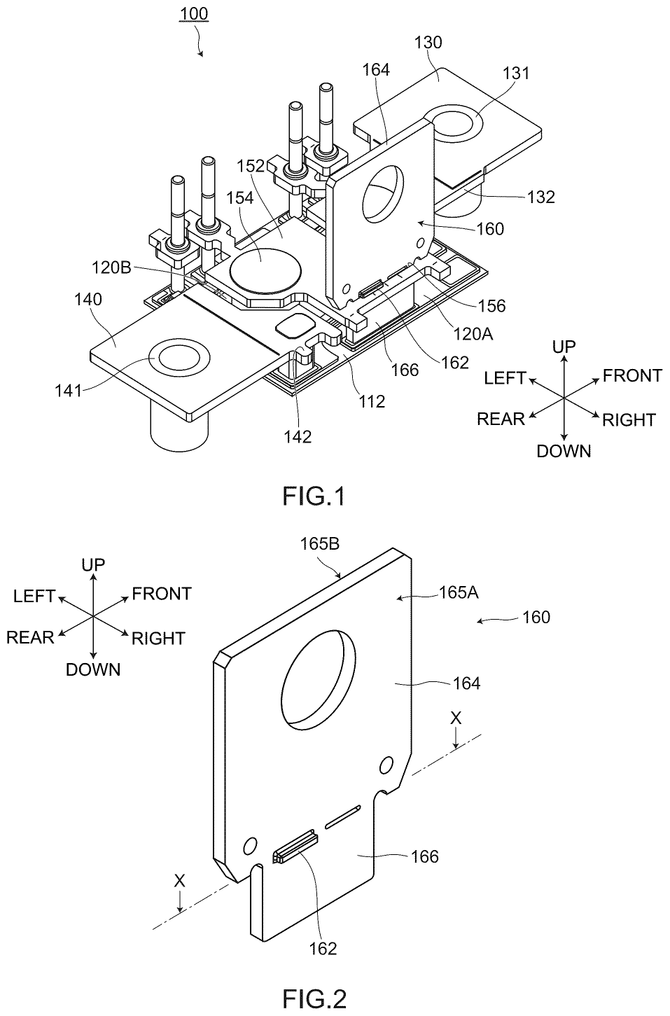

In the description made hereinafter, as illustrated in FIG. 1, the description is made by setting a longitudinal direction of an electronic module 100 as a front-rear direction, and a lateral direction of the electronic module 100 as a left-right direction. Further, a height direction of the electronic module 100 is described as up-down direction. In the direction hereinafter, “front”, “rear”, “left”, “right”, “up”, and “down” are used for the sake of convenience of the description, and do not specify the direction that the electronic module 100 is mounted when the electronic module 100 is used.

The electronic module 100 includes an insulation board 112, electronic elements 120A, 120B, a first terminal 130, a second terminal 140, a third terminal 160, a first connection frame (internal connection frame) 132, a second connection frame (internal connection frame) 142, and a third connection frame (internal connection frame) 152.

As the electronic elements 120A, 120B, for example, a power metal-oxide-semiconductor field-effect transistor (MOSFET) can be used. As the electronic element, besides the MOSFET, a suitable semiconductor element such as an IGBT, a triac, a diode or the like can be also used. The electronic elements 120A, 120B may be disposed on one surface of the insulation board 112. The electronic elements 120A, 120B are respectively formed as a semiconductor element, for example, and each of the electronic elements 120A, 120B includes an electrode not illustrated in the drawing which is formed on one surface or both surfaces of the insulation board 112. The electronic elements 120A, 120B may be other electronic elements (capacitors, for example) besides the semiconductor elements.

The insulation board 112 on which the electronic elements are mounted is a direct copper bonding board (DCB) where a metal plate for heat radiation is formed on a lower surface (back surface) of the insulation board 112. A wiring is disposed on the insulation board 112, and the electronic elements 120A, 120B are mounted on the wiring. The insulation board 112 may be a printed circuit board or the like. The insulation board 112 is formed in a rectangular flat shape, and it is preferred that the insulation board 112 is disposed at a center portion of the electronic module 100 in the front-rear direction which is the longitudinal direction.

As illustrated in FIG. 1, the first terminal 130 is disposed on a front side of the electronic module 100 in the front-rear direction. The first terminal 130 is a flat plate member having conductivity, for example, a member having a plate shape and formed of a copper plate. The first terminal 130 includes a through hole 131 which penetrates the first terminal 130 in the vertical direction. The through hole 131 has a circular shape, for example, as viewed in the vertical direction.

The first connection frame 132 is electrically connected with the first terminal 130. The first connection frame 132 is embedded in a sealing resin (not illustrated in the drawing). In the electronic module 100, the first connection frame 132 is formed integrally with the first terminal 130 using the same plate material.

The first connection frame 132 includes a through hole (symbol being omitted) which penetrates the first connection frame 132 in the vertical direction. The through hole is formed in a circular shape as viewed in the vertical direction. An upper end portion of the internal connection terminal (symbol being omitted) is fitted in the through hole. The first connection frame 132 and an electrode (not illustrated in the drawing) of the electronic element 120A are connected to each other by the internal connection terminal. The internal connection terminal is fixed to the first connection frame 132 by press-fitting, for example.

As illustrated in FIG. 1, the second terminal 140 is disposed on a rear side of the electronic module 100 in the front-rear direction. The second terminal 140 is a flat plate material having conductivity, for example, a member having a plate shape formed of a copper plate. The second terminal 140 includes a through hole 141 which penetrates the second terminal 140 in the vertical direction. The through hole 141 has a circular shape, for example, as viewed in the vertical direction.

The second connection frame 142 is electrically connect with the second terminal 140. The second connection frame 142 is embedded in a sealing resin (not illustrated in the drawing). In the electronic module 100, the second connection frame 142 is formed integrally with the second terminal 140 using the same plate material.

The electronic module 100 includes a third terminal (hereinafter referred to as “power terminal”) 160 which functions as a power terminal. As illustrated in FIG. 1, the power terminal 160 is formed of a flat plate member having conductivity, for example, a copper plate. The power terminal 160 is formed in an elongated shape where the left and right direction of the power terminal 160 becomes a plate thickness direction, and the vertical direction of the power terminal 160 becomes a longitudinal direction. The detail of the power terminal 160 is described later.

The electronic module 100 includes a third connection frame 152. The third connection frame 152 is electrically connected to the power terminal 160. The third connection frame 152 may be disposed on the same plane as the first connection frame 132 and the second connection frame 142 (on the same plane as illustrated in FIG. 1).

The third connection frame 152 includes a through hole (symbol being omitted) which penetrates the third connection frame 152 in the vertical direction. The through hole is formed in a circular shape as viewed in the vertical direction. An upper end portion of the internal connection terminal 154 is fitted in the through hole. Electrodes (not illustrate in the drawing) of the third connection frame 152 and the electronic element 120A are connected with each other by the internal connection terminal 154. The internal connection terminal 154 is fixed to the third connection frame 152 by press-fitting, for example.

### Structure of Power Terminal

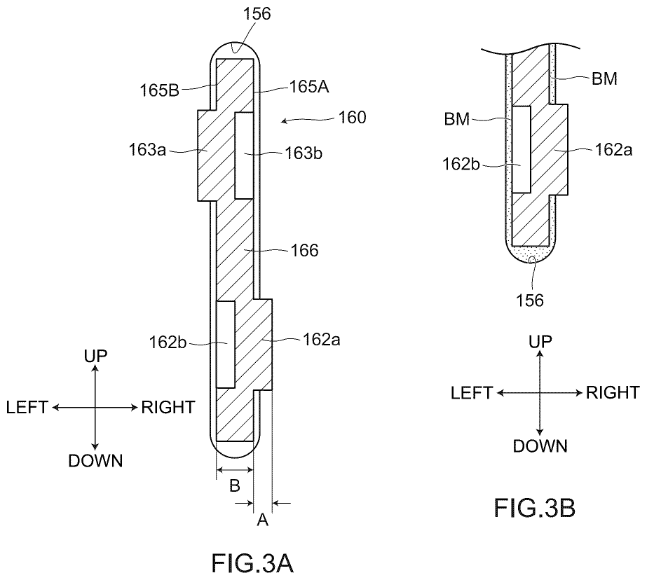

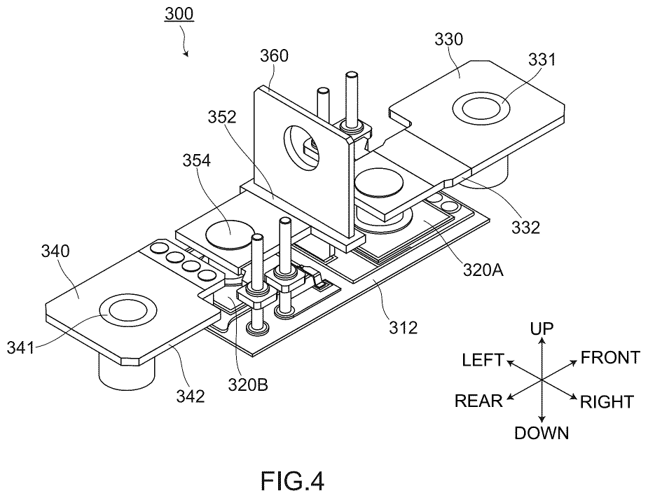

Hereinafter, the structure of the power terminal 160 is described with reference to FIG. 2. The power terminal 160 includes: an insertion portion 166 which extends in a direction (a downward direction) directed from the third connection frame 152 to the insulation board 112; and a large width portion 164 extending in a direction (an upward direction) opposite to the insulation board 112 from the third connection frame 152. The power terminal 160 is electrically connected to the third connection frame 152, the insertion portion 166 is press-fitted into the elongated hole 156 formed in the third connection frame 152 (see FIG. 1 and FIG. 3A and FIG. 3B), a distal end portion of the insertion portion 166 is brought contact with the insulation board 112, and protruding portions (convex portions) 162 which protrude in a thickness direction of the power terminal 160 from one surface 165A and the other surface of the power terminal 160 are formed at a boundary portion between the insertion portion 166 and the large width portion 164. Cross sections of the elongated hole 156 and the insertion portion 166 as viewed in the vertical direction are formed in a longitudinal direction where the front-rear direction is set as the longitudinal direction.

As illustrated in FIG. 3A, a first protruding portion 162a is formed on one surface 165A of the power terminal 160, and a second protruding portion 163a is formed on the other surface 165B of the power terminal 160. The first protruding portion 162a and the second protruding portion 163a are formed with a predetermined distance therebetween in a state that the protruding portions are directed in the opposite directions. The first protruding portion 162a is formed by pressing (half-punching) the e other surface 165B of the insertion portion 166 such that a first pressed portion (recessed portion) 162b is formed. The second protruding portion 163a is formed by pressing (half-punching) one surface 165A of the insertion portion 166 such that a second pressed portion (recessed portion) 163b is formed.

Further, a protruding height of the first protruding portion 162a and a protruding height of the second protruding portion 163a are the same. Assuming such a height as A and a plate thickness of the power terminal 160 as B, it is preferred that a relationship of A≤B/2 is satisfied. The reason that the satisfying of the relationship A≤B/2 is preferred is that, in a case where the relationship of A>B/2 is set between the height A of the protruding portion and the plate thickness B of the power terminal 160, there is a concern that a strength of the first protruding portion 162a and a strength of the second protruding portion 163a become weak. In this embodiment, the height A means, using a surface of the power terminal 160 as a reference, a length from the surface to a peak head portion of the protruding portion (see FIG. 3A).

Accordingly, in the above-mentioned configuration, the first protruding portion 162a and the second protruding portion 163a are made to protrude perpendicular to the surface of the power terminal 160 and in the opposite directions and hence, the power terminal 160 can be supported by the first protruding portion 162a and the second protruding portion 163a whereby it enables stable self-standing of the power terminal 160.

Further, as illustrated in FIG. 3B, solder BM which is a conductive bonding material is disposed between an inner peripheral surface of the elongated hole 156 and the insertion portion 166. The power terminal 160 and the third connection frame 152 are electrically connected with each other via the solder BM. This solder BM is obtained by heating the solder BM disposed on an upper surface of the third connection frame 152 corresponding to the insertion portion 166 by printing or by using a dispenser, and by making the solder BM flow into a gap formed between the insertion portion 166 and the inner peripheral surface of the elongated hole 156, and by solidifying the solder BM. The flow of the solder BM is guided using the first protruding portion 162a and the second protruding portion 163a as flow start points. Accordingly, by forming the first protruding portion 162a and the second protruding portion 163a, it enables stable wetting and spreading of the solder between the power terminal 160 and the third connection frame (lead frame) 152.

### Advantageous Effects Acquired by Electronic Module 100 According to Embodiment

The electronic module 100 according to the embodiment includes: the insulation board 112 on which the electronic elements 120A, 120B are mounted; the power terminal 160 having a flat plate shape which is connected to the wiring pattern on the insulation board 112; and the internal connection frame 152 which supports the power terminal 160 and electrically connects the electronic elements 120A, 120B and the power terminal 160 to each other, wherein the internal connection frame 152 is a member having a flat plate shape which has the elongated hole 156. The power terminal 160 includes: the insertion portion 166 which extends in a direction toward the insulation board 112 from the internal connection frame 152; and the large width portion 164 which extends in a direction opposite to the insulation board 112 from the internal connection frame 152. The power terminal 160 is electrically connected to the internal connection frame 152, the insertion portion 166 is press-fitted into the elongated hole 156 formed in the internal connection frame 152, and the distal end of the insertion portion 166 is brought into contact with the insulation board 112, and the first protruding portion 162a and the second protruding portion 163a which protrude in the thickness direction of the power terminal 160 from one side surface 165A and the other side surface 165B of the power terminal 160 are formed on the boundary portion between the insertion portion 166 and the large width portion 164. Accordingly, the power terminal 160 can be supported by the first protruding portion 162a and the second protruding portion 163a and hence, it enables stable self-standing of the power terminal 160 and, at the same time, it enables stable wetting and spreading of the solder BM between the power terminal 160 and the internal connection frame 152.

Further, according to the electronic module of the embodiment, at least one protruding portion 162 is formed on one surface 165A, and at least one protruding portion 162 is formed on the other surface 165B. Accordingly, it enables stable self-standing of the power terminal 160 with certainty.

Further, according to the electronic module of the embodiment, assuming the protruding height of the protruding portion 162 as A and the plate thickness of the power terminal 160 as B, the relationship between the protruding height A and the plate thickness B is set to satisfy the relationship of A≤B/2 and hence, the protruding portion 162 can maintain a strength of a fixed value or more.

### Modification

In the above-mentioned example, the case where one protruding portion is formed on one surface of the power terminal and one protruding portion is formed on the other surface of the power terminal is exemplified. However, a case may be considered where two or more protruding portions are formed on one surface of the power terminal and two or more protruding portions are formed on the other surface of the power terminal. In this case, it is preferred that a distance between the protruding portions on one surface and a distance between the protruding portions on the other surface are equal. With such a configuration, the number of the protruding portions is increased and hence, it is possible to enhance self-standing of the power terminal 160 with more certainty.

The present invention is not limited to the above-mentioned embodiment, and various modifications are conceivable without departing from the gist of the present invention.

1. An electronic module comprising:
a board on which an electronic element is mounted;
a power terminal having a flat plate shape which is connected to a wiring pattern on the board; and
an internal connection frame which supports the power terminal and electrically connects the electronic element and the power terminal to each other, wherein
the internal connection frame is a member having a flat plate shape that has an elongated hole,
the power terminal includes: i an insertion portion which extends in a direction toward the board from the internal connection frame; and a large width portion which extends in a direction opposite to the board from the internal connection frame,
the power terminal is electrically connected to the internal connection frame,
the insertion portion is press-fitted into the elongated hole formed in the internal connection frame and a distal end of the insertion portion is brought into contact with the board, and
a protruding portion which protrudes in a thickness direction of the power terminal from one side surface and a protruding portion which protrudes in the thickness direction of the power terminal from the other side surface of the power terminal are formed on a boundary portion between the insertion portion and the large width portion.

2. The electronic module according to claim 1, wherein the at least one protruding portion is formed on the one surface and the at least one protruding portion is formed on the other surface.

3. The electronic module according to claim 1, wherein, assuming a height that the protruding portion protrudes as A and a plate thickness of the power terminal as B, a relationship of A≤B/2 is satisfied.

4. The electronic module according to claim 2, wherein, assuming a height that the protruding portion protrudes as A and a plate thickness of the power terminal as B, a relationship of A≤B/2 is satisfied.
